(19) United States
(12) Patent Application Publication
(10) Pub. No.: US 2023/0264639 A1
(43) Pub. Date: Aug. 24, 2023

(54) CONTROL DEVICE FOR A VEHICLE

(71) Applicant: ZF Friedrichshafen AG, Friedrichshafen (DE)

(72) Inventors: Timm Muntel, Friedrichshafen (DE); Istvan Hegedüs-Bite, Eriskirch (DE); Hubert Bichelmeier, Tettnang (DE); Bastian Hubracht, Salem (DE); Mohammad Alsharif, Tettnang (DE); Gowtham Perumalsamy, Markdorf (DE); Ilker Bagci, Ravensburg (DE)

(73) Assignee: ZF Friedrichshafen AG, Friedrichshafen (DE)

(21) Appl. No.: 18/003,997

(22) PCT Filed: Jun. 28, 2021
(86) PCT No.: PCT/EP2021/067699

§ 371 Date: Dec. 30, 2022

(30) Foreign Application Priority Data
Jul. 1, 2020 (DE) 10 2020 208 216.2

(51) Int. Cl. B60R 16/023; B60R 16/03; H05K 5/00

(52) U.S. Cl. CPC B60R 16/0231; B60R 16/03; H05K 5/0069

(57) ABSTRACT

A control device for a vehicle may include a housing, a first interface for connecting to a communication network in the vehicle, a connecting unit that is connected to the first interface, a first assembly connected to the connecting unit which is configured to control a function in the vehicle, and a port for a second assembly that is configured to control another function in the vehicle.

### RELATED APPLICATION

This application is a filing under 35 U.S.C. § 371 of International Patent Application PCT/EP2021/067699, filed Jun. 28, 2021, and claiming priority to German Patent Application 10 2020 208 216.2, filed Jul. 1, 2020. All applications listed in this paragraph are hereby incorporated by reference in their entireties.

### TECHNICAL FIELD

The present disclosure relates to a control device, in particular for use in a vehicle.

### BACKGROUND

There is a control device in a vehicle that is configured to carry out a predetermined function in the vehicle. The vehicle normally has a projected service life in the range of decades. If the control device in an older vehicle needs to be replaced, it may be difficult to obtain a suitable replacement. A control device produced when the vehicle was manufactured may have aged because of chemical processes acting on electronic components and may not still be fully fit for service. Manufacturing and implementation methods in microelectronics may also have changed, such that it may not still be possible to produce an identical control device. Semiconductors produced with modern processes may have other properties and might require a different operating voltage. It may therefore be difficult to modernize the control device.

Furthermore, control devices in vehicles are usually only designed for a single specific purpose. An additional execution of another function is not intended. Within narrow boundaries, a computer program executed on the control device may be modified or replaced. A significant modification of the program is not generally possible, however, because security functions may prevent a replacement of larger portions of program code, and it may not be possible to modify the resources of the control device retroactively, in particular with regard to processing speed, memory or peripheral devices.

### BRIEF DESCRIPTION

One of the fundamental objects of the present invention is to create an improved control device for a vehicle that can be retroactively modified. A control unit for a vehicle comprises a housing, a first interface for connecting to a communication network in the vehicle, a connecting unit connected to the first interface, a first assembly connected to the connecting unit, configured to control a function in the vehicle, and a port for a second assembly for controlling another function, in particular in the vehicle. The other function can be an independent function, a part of a function carried out by the first assembly, or an expansion thereof.

The control device can be prepared for a new purpose through the insertion of a second assembly. This can comprise an expansion of an existing functionality that was previously fulfilled by the first assembly, or an addition of a new functionality. Furthermore, the second assembly may use a different technology than the first assembly. If, for example, a production technology for microelectronics has changed between when the control device was produced and when the second assembly was produced, the second assembly can be produced with current technology and designed for operation in the older control device. The control device be used for a long time in the vehicle, and modified at a hardware level as needed for changes in the requirements for the vehicle.

There can be one or more second assemblies, each of which can correspond to the first assembly. The assemblies may also be created differently, in particular with regard to their purpose, performance or design.

When an outdated assembly in the vehicle is replaced, use can be made of current technology. Functional components in the control device can be salvaged, such that waste in terms of electronics components can be kept to a minimum. A functional assembly removed from a control device so that it can be replaced with a more powerful assembly can still be used in another control device. The assembly can be checked to make sure it still functions properly for this. It can also be ensured that the number of hours in which it has been put to use does not exceed a predetermined value. The assembly can comprise a counter that records the number of hours of operation for this. In one embodiment, an assembly can determine when it is nearing the end of its service life and issue a signal indicating that it needs to be replaced before the assembly malfunctions. An assembly's configuration can be stored externally, e.g. in another control device in the vehicle, or in a server or cloud, so that it can be used if needed for a replacement assembly.

In a first variation, the connecting unit is designed to be connected to the assemblies. The assemblies can be operated at the connecting unit with the same hierarchical status. The assemblies can also be inserted in different ports on the connecting unit. In one embodiment, the assemblies can be arbitrarily assigned to different ports. The ports can each define an aspect ratio of the assembly that is inserted therein, and/or maximum electrical or communication values. The ports can be substantially identical, such that it does not matter where the assemblies are inserted. The ports can also differ, e.g. with regard to available space, average temperature of a cooling fluid, or logical priority when used on a data bus.

In a second variation, the first assembly is configured to be connected to the second assembly. The second assembly may not be connected directly to the connecting unit in this case, and instead may be electrically, communicatively and/or mechanically dependent on the first assembly. This variation is ideal when the first assembly delegates a predefined function to the second assembly, e.g. the processing of a data stream or receiving sensor values. The first assembly can provide a predetermined base function independently of the second assembly, and be prepared for fulfilling an additional or expanded function by the addition of the second assembly. If numerous second assemblies are used, the first assembly may coordinate their functions.

The port can provide a mechanical attachment and/or electrical connection for the other assembly. In one embodiment, a port comprises an electrical socket for an assembly. The assembly can be connected to and disconnected from the port. An assembly can be inserted or removed without tools.

The control device can also comprise a second interface for connecting to a power supply network in the vehicle. The power supply network can provide electricity for operating the control device. Electricity at the second interface can be provided to the connecting unit and/or a first or second assembly.

The second interface can also be configured to be connected to a redundant power supply. By way of example, a first plug-in connection can be used for connecting to a simple power supply, or a second plug-in connection can be used for connecting to a redundant power supply on the control device. In another embodiment, the control device comprises a plug-in connection for use at a redundant power supply, in which the plug-in connection can also be connected to a complimentary element for simple power supply in the vehicle if necessary.

The housing can satisfy a predefined protection classification with regard to its sealing properties. The protection classification can be defined according to DIN EN 60529 and DIN 40 050 Part) (IP00 to IP68), and fulfill specifications regarding impermeability to foreign bodies and/or water. The housing can also protected in a predefined manner against fire, acids, fuel, grease, humidity, vibrations or magnetism. The housing can also ensure a predefined electromagnetic compatibility (EMC).

The manner or extent to which the housing protects its contents can be selected on the basis of where it is intended to be placed in the vehicle. By way of example, the vehicle may have an interior for transporting passengers, and the control device may be placed inside or outside this interior. It may not be as important to protect against water in the interior than when it is located somewhere on the exterior.

The control device can comprise a securing element for mechanically attaching it to the vehicle, with a vibration damper placed between the housing and the securing element. The vibration damper can be designed to cushion against impacts and/or vibrations in a predetermined frequency or amplitude range.

The connecting unit can be configured for communication using a first protocol over the first interface and using a second protocol with the at least one assembly. The connecting unit can communicate between the protocols, and support a CAN bus, FlexRay bus or multifunction vehicle bus (MVB) for communication toward the vehicle. A PCIe bus can be used to communicate toward an assembly, for example.

The connecting unit can also be replaced on the control device. In particular, the control device can be configured to mechanically support replacement of the connecting unit. The connecting unit can be releasably connected to the housing for this. Electric or communicative requirements for the connecting unit can be determined by the first interface or one of the assemblies.

According to a second aspect of the present invention, there is a system that comprises the control device described herein and at least one second assembly, which is designed to be inserted in the control device and control a function in a vehicle. The assemblies can differ from one another, and the functions can differ from one another. In one embodiment, the second assembly is configured to execute a predefined function for the first assembly, and the first assembly is configured to control a function in the vehicle. The system results in a modular assembly of the control device, such that predefined requirements for the vehicle are fulfilled in a flexible manner. In particular, control devices with different capabilities can be obtained with different second assemblies, a large portion of the components of which can be identical or similar.

According to another aspect of the present invention, a vehicle comprises the control device described herein. The vehicle can comprise permanently installed components, which the control device is configured to control, or with which the vehicle is controlled through the control device. Specifically, these permanently installed components can comprise a drive system, braking system, or steering system for the vehicle.

### BRIEF DESCRIPTION OF THE DRAWINGS

The invention shall be described below in greater detail in reference to the attached figures, in which:

FIG. 1 shows a vehicle and a control device; and

FIG. 2 shows another control device for a vehicle.

### DETAILED DESCRIPTION

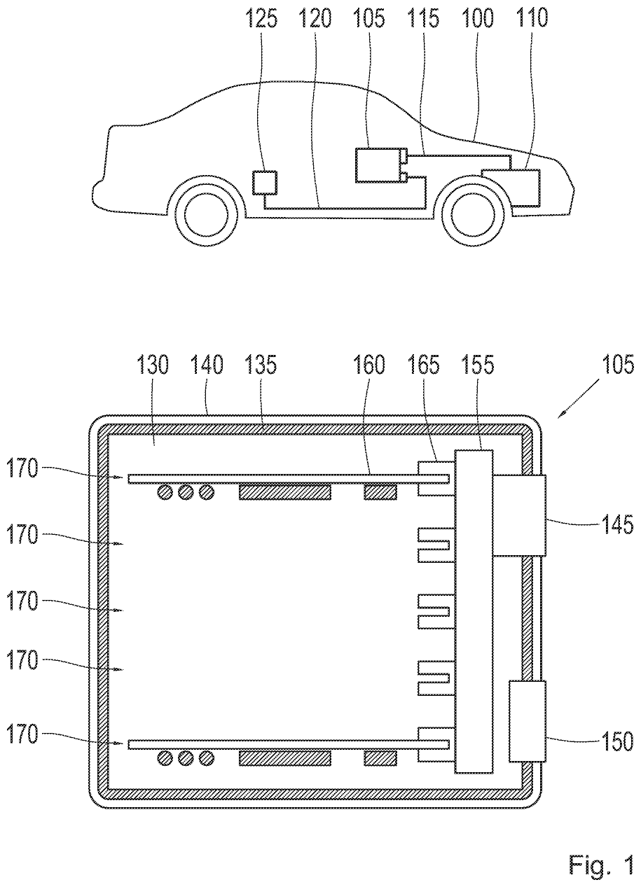

FIG. 1 shows a schematic illustration of a vehicle 100 with a control device 105 in the upper part and an enlarged schematic illustration of the control device in the lower part. By way of example, the vehicle is a motor vehicle, preferably a passenger automobile, and comprises at least one permanently installed component, which may be necessary for operating the vehicle 105. By way of example, the drive motor 110 is indicated as such a component in FIG. 1, while other possible components comprise a brake system or steering system. There can also be other devices for auxiliary functions such as opening or closing windows or doors, adjusting seats, or for an air conditioning system (HVAC).

The vehicle 105 preferably contains a communication bus 115 with which messages can be sent between components 105, 110. There is also preferably a power supply network 120, which normally comprises a power source 125 that supplies electricity to the components 105, 110 in the vehicle 100. The power source 125 can be a battery or an electric motor, which can be powered by the drive motor 110.

The control device 105 comprises a housing 130 that is configured to protect the components therein against environmental effects. The housing 130 can preferably be opened and closed without damaging it. In one embodiment, the housing 130 is hermetically sealed against dust or liquids. The housing is preferably designed to be placed in the vehicle 105 where it is protected, at least to a certain extent, against damaging environmental effects that may occur in the vehicle 100, in particular water spray, grease, acids, fuel, dust, or high temperatures. The housing 130 is also preferably easy to access. By way of example, the housing 130 can be placed in the interior of the vehicle 100, i.e. in the passenger compartment. The housing 130 can be concealed for practical or aesthetic purposes, e.g. with a cladding, floor mat, or in a service compartment.

A mechanical connection between the housing 130 and the vehicle 100 can comprise a vibration damper 135 that is designed to cushion the control device 105 against vibrations and/or impacts to the vehicle. The vibration damper 135 can comprise an elastomer, rubber, or a combination of an elastic element and a cushioning element, in the manner of a shock absorber. In one embodiment, a securing element 140 such as a base plate or frame is secured to the vehicle 100, and the housing 130 can be attached to the securing element 140 and preferably secured or locked in place mechanically. Electrical connections between the control device 105 and the vehicle 100 can be activated through the insertion and terminated through the removal thereof. In another embodiment, the control device 105 is permanently connected to the securing element 140. To remove the control device 105 from the vehicle 100, the securing element 140 can be detached from the vehicle 100. Electrical connections to the control device can be separated manually.

The housing 140 preferably has a first interface 145 for connecting to the communication network 115 and a second interface 150 for connecting to the power supply network 120.

The first interface 145 can comprise a number of electrical contacts that can be connected to a pair of data lines in a CAN bus, for example. There can also be additional signal, shielding or communication lines. The first interface 145 can also support information transmission in a manner other than electrically, e.g. by means of light. The first interface 145 normally functions bidirectionally. There can be at least one communication protocol for communication with vehicle components.

The second interface 150 normally comprises at least a pair of electrical connections, although it can also have more, for conveying different electrical currents or signals. In particular, the second interface 150 can be configured to be connected to a redundant power supply. In this case, the vehicle 100 normally comprises at least two power supply networks 120, which are at least partially separated from one another.

The first interface 145 is connected to a connecting unit 155 inside the housing 130. The connecting unit 155 is connected to at least one assembly 160, which is configured to execute a predetermined function in the vehicle 100. The assembly 160 is preferably connected to the connecting unit 115 with a releasable connection 165.

The connecting unit 155 is preferably configured to communicate with the assembly 160, for which there can be a second communication protocol, which can differ from the first. By way of example, a PCIe Bus can be used between the connecting unit 155 and an assembly 160, on which another protocol is defined that that for the first interface 145 in the form of a CAN bus. The connecting unit 155 can translate messages in the communication protocols such that they are compatible with one another, and thus convert or translate addresses, arbitrations or transmission speeds, for example. It should be noted that numerous hierarchical communication protocols can normally be used at an interface 145, 165, as described, for example, for the ISO layer model for communication. A transformation of the connecting unit 155 can impact one or more layers.

The housing 130 has a port 170 for the assembly 160. The port 170 can comprise mechanical, electrical, or communicative specifications for the assembly 160. By way of example, a port 170 can define the available space for the assembly 160in terms of shape and size. There are numerous ports 160 in the present case, which can provide identical spaces, although different spaces can be made available in another embodiment. The mechanical attachment of an assembly 160 can also be defined by the port 170, e.g. with respect to a notch, edge, or hole that the assembly 160 must have in order to fit correctly in the housing 130.

The port 170 can also determine how much energy is available to an assembly 160 inserted therein. Communication between the assembly 160 and the connecting unit 155 can also be defined. Energy and communication can be conveyed over a combined connection 165, or there can be separate connections 165.

In another embodiment, there can be a cooling device in the housing 130, which can comprise a bearing surface for absorbing thermal energy from an assembly 160. The bearing surface can be connected to a heat sink on the outside of the housing 130 in a thermally conductive manner. In another embodiment, the bearing surface can be cooled by means of a closed cooling system. Alternatively, a gaseous coolant can flow through the housing 130. The amounts of energy that are to be absorbed from an assembly 160 by the cooling device or bearing surface may differ at the different ports 170.

In the present illustration, numerous assemblies 160 can each be placed in a port 170, such that each assembly 160 is then connected to the connecting unit 155. Connections can also be obtained between individual assemblies 160. One assembly 160 can also occupy numerous ports 170, in which case it can make use of just one or numerous connections 165 to the connecting unit 155. A number of ports 170 in the housing 130 is normally predefined, and there is normally one connection 165 for each port 170, even if no assembly 160 is inserted therein.

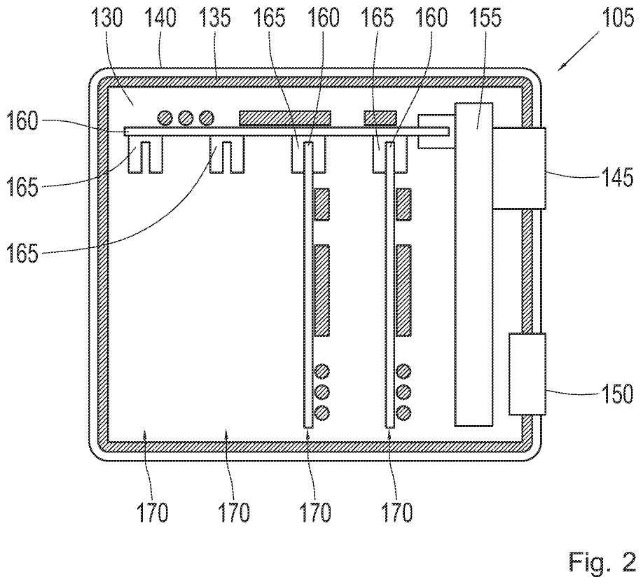

FIG. 2 shows another embodiment of a control device 105. Unlike in the embodiment shown in FIG. 1, just one first assembly 160 is connected to the connecting unit 155. One or more second assemblies 160 can be attached to the first assembly 160 by means of the connections 165 intended for this, and connected thereto. In this constellation, the first assembly 160 can have a master status with respect to the second assemblies 160, forming a master-slave configuration.

In another embodiment, a second assembly 160 can also be connected to the second interface 150 by means of another connection.

### REFERENCE SYMBOLS

100 vehicle
105 control device
110 drive motor
115 communication bus
120 power supply network
125 power source
130 housing
135 vibration damper
140 securing element
145 first interface to communication bus
150 second interface to power supply network
155 connecting unit
160 assembly
165 connection
170 port

1. A control device for a vehicle, the control device comprising:
a housing;
a first interface for connecting to a communication network in the vehicle;
a connecting unit that is connected to the first interface;
a first assembly connected to the connecting unit, which is configured to control a function in the vehicle; and
a port for a second assembly that is configured to control another function in the vehicle.

2. The control device according to claim 1, wherein the connecting unit is configured to be connected to the assemblies.

3. The control device according to claim 1, wherein the first assembly is configured to be connected to the second assembly.

4. The control device according to claim 1, wherein the port provides a mechanical attachment and electrical connection to the other assembly.

5. The control device according to claim 1, also comprising a second interface for connecting to a power supply network in the vehicle.

6. The control device according to claim 5, wherein the second interface can be configured to be connected to a redundant power supply.

7. The control device according to claim 1, wherein the housing satisfies a specific protection classification regarding sealing properties.

8. The control device according to claim 1, also comprising a securing element for mechanically attaching to the vehicle, wherein a vibration damper is placed between the housing and the securing element.

9. The control device according to claim 1, wherein the connecting unit is configured to communicate over the first interface by means of a first protocol, and with the at least one assembly by means of a second protocol.

10. The control device according to claim 1, wherein the connecting unit is replaceable.

11. A system comprising the control device according to claim 1, and at least one second assembly, which is configured to be inserted in the control device and control a function in a vehicle.

12. A vehicle, comprising the control device according to claim 1.

13. The vehicle according to claim 12, comprising a permanently installed component, wherein the control device is configured to control the component.
